(19) United States
(12) Patent Application Publication
(10) Pub. No.: US 2022/0344972 A1
(43) Pub. Date: Oct. 27, 2022

(54) ENERGY CONVERSION SYSTEMS AND METHODS

(71) Applicant: Dark Radiance LLC, Acton, MA (US)

(72) Inventors: Brian Ahern, Acton, MA (US); Jean-Francois Leitner, Brussels (BE); Arthur Manelas, Pelham, NH (US)

(21) Appl. No.: 17/724,362

(22) Filed: Apr. 19, 2022

Related U.S. Application Data
(60) Provisional application No. 63/217,099, filed on Jun. 30, 2021.
(60) Provisional application No. 63/177,671, filed on Apr. 21, 2021.

(51) Int. Cl. H02J 50/00; H02J 7/00; H02J 50/10; H01F 3/14; H01F 5/02; H01F 1/00

(52) U.S. Cl. CPC H02J 50/001; H02J 7/0042; H02J 50/10; H02J 50/005; H01F 3/14; H01F 5/02; H01F 1/0063; H02J 2300/22; H01F 2003/106

(57) ABSTRACT

A novel transformer circuit employing multi-axis windings around a large magnetic billet receives and amplifies the energy from a flux of energetic waves emanating from the sun and other celestial bodies and entities throughout the environment. A clean source of solar energy can be harvested with an energy density that is at least 50 times greater than photon-based collectors.

### CROSS-REFERENCE TO RELATED APPLICATIONS

This application claims the benefit of U.S. Provisional Application Nos. 63/177,671 filed Apr. 21, 2021 and 63/217,099 filed Jun. 30, 2021, the disclosures of each of which are incorporated herein, in their entirety, by this reference.

### FIELD OF THE INVENTION

The present invention relates generally to energy conversion devices, and more particularly, to system and method of extracting non-photonic wave energy emanating from celestial bodies such as the sun and other entities throughout the universe.

### BACKGROUND OF THE INVENTION

Energetic waves emanating from the sun have been predicted from advanced electrodynamic theory. These waves were predicted in the 1930's and emanate from celestial bodies all around us including the stars as well as a great abundance from the sun, among other entities throughout the universe. These waves have extremely penetrating properties and are difficult to detect. They are also emitted from with extremely high energy densities. Efficient conversion of the energy from these waves, however, have not yet been achieved by the physics community. To date, there has also been little consensus on the mechanisms for capturing these energy waves and converting them to useful purposes.

### SUMMARY OF THE INVENTION

The following presents a simplified summary of the innovation in order to provide a basic understanding of some aspects of the invention. This summary is not an extensive overview of the invention. It is intended to neither identify key or critical elements of the invention nor delineate the scope of the invention. Its sole purpose is to present some concepts of the invention in a simplified form as a prelude to the more detailed description that is presented later.

Presently disclosed is a lithium-ion battery pack that has been self-charging when energized with a novel transformer circuit that acts as an antenna for receiving and transmitting non-photonic waves. The device described herein is the first reliable apparatus for detecting and harvesting energy from the elusive energy waves of celestial bodies such as the sun and the stars in the universe.

Disclosed in one embodiment is a novel transformer circuit employing three bifilar windings around a large ferrite billet receiver and amplifying the energy from a flux of energetic waves emanating from the sun. Presently disclosed are systems and methods directed to harvesting clean solar energy source to deliver energy density that is at least 50 times greater, or at least 100 times greater than conventional photon-based solar-based collectors.

In some embodiments, the presently disclosed apparatus can operate continuously for at least two months, or at least four months, or at least six months, or longer, without any significant output degradation. In one embodiment, the apparatus includes a lithium-ion battery pack (e.g., at about 175 volts and at about 300 pounds) energized device capable of continuously charging the battery without degradation. This is accomplished by real energy source, the energy source being harvested from high energy, non-interacting waves of celestial bodies such as the sun and the stars in the universe. In another embodiment, the lithium-ion battery pack can be at about 180 volts and have varying weights.

In one embodiment, the energetic waves from the sun can be captured by an antenna structure formed with ferrite billets and bifilar windings, along with high frequency electromagnetic (EM) electronics. This wave phenomena action, however, is unlike customary transverse EM waves. Instead, a new class of magnetic materials and matching circuity may be required for the energy harvesting process.

In one embodiment, magnetostrictive materials expand and contract longitudinally with the application of pulsed EM fields. In some embodiments, the bifilar windings around the ferrite core can couple resonantly with the energetic waves and establish the conditions to receive and amplify incoming waves.

In one embodiment, an apparatus for harvesting energy waves includes a battery, a power supply, a billet core, and a plurality of coils adjacent at least a portion of the billet core, whereby the billet core is configured to harvest energy from an environment. In an embodiment, the power supply may be tunable and pulsed, and the billet core may be a magnetic billet core. In another embodiment, the plurality of coils may be wires or coils wrapped around the billet core. In operation, the disclosed apparatus is capable of forming a Sub-Threshold magnon Bose-Einstein Condensate (STmBEC) for purposes of harvesting energy from entities that exist in the environment. In one embodiment, the energy harvested is from neutrino waves emitted by the sun. For instance, the neutrino flux can be coupled to a STmBEC material. In another embodiment, the energy harvested is from magnetically excited monopoles.

In yet another embodiment, the energy harvested may include scalar longitudinal waves (SLW's) from the environment. SLW's are predicted from extensions of the electrodynamic equations predicted by Maxwell's Equations. Like neutrinos, SLW's have not yet been universally accepted by the physics community, but are believed to be emitted from every star including our own sun with high energy density, and are predicted to have penetrating properties similar to neutrinos. In fact, SLW's and neutrinos may be the same entity with different names and different boundary conditions. In one embodiment, SLW's can be harvested in accordance with the presently disclosed embodiments. Maxwell's modified equations suggest that SLW's may be captured by a unique antenna structure formed with ferrite billets and bifilar windings and high frequency EM waves in accordance with the present disclosure.

In one embodiment, the disclosed apparatus is capable of forming a Bose-Einstein Condensate (BEC) for purposes of harvesting energy from entities that exist in the environment. In this embodiment, the harvested energy can include neutrino flux coupled to a BEC material.

In some embodiments, the entities that exist in the environment can include neutrino flux, sterile neutrino flux, longitudinal spin wave, and scalar longitudinal wave, among other entities. In one embodiment, the energy that is harvested can be directed to charge the battery. In one embodiment, the battery can be a lithium-ion battery pack. In another embodiment, the power supply can also include a lithium-ion battery. In yet another embodiment, the battery powers the power supply. In yet another embodiment, the power supply is configured to resonantly charge the battery.

In some embodiments, the billet core is formed of a ferrite solid material, a ferroelectric solid material, or a ferrostrictive solid material, among other suitable materials. In some embodiments, the billet core is processed with a grain dimension of less than about 100 nanometers, or less than about 50 nanometers, among other suitable grain sizes.

In one embodiment, the billet core is magnetically conditioned to produce field gradients to maximize the energy from the environment for charging the battery. In another embodiment, the billet core is resonantly coupled to the battery for charging the battery with the energy from the environment. In this instance, the battery can be used for powering the power supply, and the charging can be accomplished with existing circuit wires.

In one embodiment, the apparatus further includes a metallic element blended with the billet core, where the metallic element is selected from the group consisting of strontium, barium, manganese, nickel and zinc, among other suitable metals or compounds.

In one embodiment, the plurality of coils adjacent at least a portion of the billet core includes a plurality of bifilar wires circumferentially wrapped around the billet core. In another embodiment, the plurality of bifilar wires includes copper coils. In yet another embodiment, the plurality of coils may be plurality of wires wrapped around a magnetic billet core to serve as an antenna for neutrino waves.

In one embodiment, the energy from the environment can be directed to charge the battery. In another embodiment, the energy directed to charge the battery can be accomplished without current flowing through the plurality of coils.

In some embodiments, the energy from the environment includes neutrino waves emitted by a star, or energy from magnetic monopoles, among other energy waves. In another embodiment, the apparatus further includes electrical input to the billet core including unipolar pulses.

In one embodiment, the billet core may exhibit magnetic properties. In another embodiment, an apparatus according to presently disclosed embodiments may be used for magnetocaloric cooling.

These and other features and advantages will be apparent from a reading of the following detailed description and a review of the associated drawings. It is to be understood that both the foregoing general description and the following detailed description are explanatory only and are not restrictive of aspects as claimed.

### BRIEF DESCRIPTION OF THE DRAWINGS

Various aspects of at least one example are discussed below with reference to the accompanying figures, which are not intended to be drawn to scale. The figures are included to provide illustration and a further understanding of the various aspects and examples and are incorporated in and constitute a part of this specification but are not intended as a definition of the limits of the disclosure. In the figures, identical or nearly identical components illustrated in various figures may be represented by a like reference character or numeral. For purposes of clarity, not every component may be labeled in every figure.

The invention will be more fully understood by reference to the detailed description, in conjunction with the following figures.

FIG. 1 is a device configured to harvest energy from the environment according to an embodiment.

FIG. 2A is an apparatus configured to harvest energy from the environment according to an embodiment.

FIG. 2B is an apparatus configured to harvest energy from the environment according to another embodiment.

FIG. 3 is a battery charging profile of an apparatus according to one embodiment.

FIG. 4 is a battery charging profile of an apparatus according to another embodiment.

FIG. 5 is a bifilar wire or coil winding according to an embodiment.

FIG. 6 are temperature profiles of an apparatus according to an embodiment.

FIG. 7 is an illustration of magnetic conditioning of a billet core according to an embodiment.

FIG. 8 is an illustration of conditioning with complex field arrangement according to another embodiment.

FIGS. 9A-9B illustrate two different conditioned billets in accordance with the present disclosure.

FIGS. 9C-9D illustrate the field strength variations of ferrite billets.

FIG. 10 is a bifilar wire or coil winding according to another embodiment.

FIG. 11 is an exemplary square wave input that may be used in conjunction with the present disclosure.

### DETAILED DESCRIPTION OF THE INVENTION

Examples of the systems, methods and apparatuses discussed herein are not limited in application to the details of construction and the arrangement of components set forth in the following description or illustrated in the accompanying drawings. The systems, methods and apparatuses are capable of implementation in other examples and of being practiced or of being carried out in various ways. Examples of specific implementations are provided herein for illustrative purposes only and are not intended to be limiting. In particular, functions, components, elements, and features discussed in connection with any one or more examples are not intended to be excluded from a similar role in any other examples.

Examples disclosed herein may be combined with other examples in any manner consistent with at least one of the principles disclosed herein, and references to “an example,” “some examples,” “an alternate example,” “various examples,” “one example” or the like are not necessarily mutually exclusive and are intended to indicate that a particular feature, structure, or characteristic described may be included in at least one example. The appearances of such terms herein are not necessarily all referring to the same example.

Also, the phraseology and terminology used herein is for the purpose of description and should not be regarded as limiting. Any references to examples, components, elements, acts, or functions of the computer program products, systems and methods herein referred to in the singular may also embrace embodiments including a plurality, and any references in plural to any example, component, element, act, or function herein may also embrace examples including only a singularity. Accordingly, references in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms

The subject innovation is now described with reference to the drawings, wherein like reference numerals are used to refer to like elements throughout. In the following description, for purposes of explanation, numerous specific details are set forth in order to provide a thorough understanding of the present invention. It may be evident, however, that the present invention may be practiced without these specific details. In other instances, well-known structures and devices are shown in block diagram form in order to facilitate describing the present invention.

Energetic weakly interacting waves emanating from the sun have been predicted since 1930 by Wolfgang Pauli. To date, however, there has been little consensus on the mechanisms for capturing the energy from these entities and converting them into useful purpose. Disclosed embodiment is a lithium-ion battery pack that appears to have been self-charging when energized with a novel transformer circuit that acts as an antenna for receiving and transmitting non-photonic waves from the sun, stars and other entities around the environment.

Efficient conversion of the energy is from the flux of weakly interacting entities. There are two possible candidates with similar properties. They are known as neutrinos and separately as axions. Extracting energy from these waves has not yet been reliably achieved by the physics community. Neutrinos are emitted from every star including our own sun with high energy density. The properties of axions are even more obscure. Both waves have extremely penetrating properties and are difficult to detect. The embodiments of the present disclosure are the first reliable device, apparatus, system and method for detecting and harvesting energy from these elusive entities.

These energetic entities are not new, yet they have heretofore resisted harvesting and put to useful work. This novel circuitry has demonstrated battery charging energy density that is at least 50 times greater, or at least 100 times greater than the most efficient solar cell harvesting lower energy photons. The device, according to some embodiments, may also respond to coronal mass ejections and nova explosions. The device, according to an embodiment, is the only known system that responded strongly to these astronomical entities.

This disclosure is not merely a theoretical exercise. A real, albeit invisible energy source is interactive with the magnetic configurations provided by the device. The terms apparatus and device may be used interchangeably to represent an embodiment of the present invention. In one embodiment, a device has operated continuously for over six months without output degradation. In this embodiment, a lithium-ion battery pack (e.g., about 175 volts, about 300 pounds) energized the device and charged the same battery in an apparent violation of the First Law of Thermodynamics.

The First Law of Thermodynamics is not violated. There is a real cosmic energy source, and the device is able to extract such energy from the cosmos. The data extracted from this device showed evidence of harvesting these high energy, non-interacting waves. These waves were predicted in the 1930's and are emanating from all the stars as well as in great abundance from the sun. These waves can be captured by a unique antenna structure formed with magnetic billets, coil windings about the three axes of the billets, and high frequency electromagnetic (EM) waves. This wave phenomena action is unlike customary transverse EM waves. A new class of magnetic materials and matching circuitry are required for the energy harvesting.

Magnetostrictive materials expand and contract longitudinally with the application of pulsed EM fields. In this invention the axes windings around the “waist” of the ferrite core couple resonantly with the energetic waves and establishes the magnetic conditions to receive and amplify incoming neutrino waves.

The waves are neutrinos and the lack of data about neutrino properties arise from a lack of detector technology. That is, because most detectors are designed for transverse EM wave phenomena with linear properties. This invention includes a proprietary antenna circuit that is mated to a nonlinear, dynamic, magnetic material.

Energy capture of neutrinos applies equally to axions. Axions were first predicted in 1977 in response to inconsistencies in the Grand Unified Theory. Like neutrinos, axions are non-interacting but omnipresent. Axions may be the energy harvested as their properties are nearly the same as neutrinos. For purposes of this disclosure axions and neutrinos will be treated as equivalent entities.

Transverse EM waves have driven the world's economy for the past 150 years. Now it is time to consider the properties of neutrinos interacting with a magnetic effect like a Bose-Einstein Condensate (BEC) environment. The magnetic waves inducted into the billet amplify the electric fields in a transformer resonant circuit and energy conversion via a novel processes is achieved.

### BEC and STmBEC

Bose-Einstein Condensates (BEC's) are newly discovered class of matter that has operated at room temperature. Quasi-particles in magnetic material condensate are known as magnons. A magnon is an ephemeral entity that oscillates in and out of existence. This condition can be stabilized by parametric pumping of the material at a resonant frequency above the thermalization frequency.

In one embodiment, magnons can be produced by the optical pumping of the ferrite billet. In another embodiment, barium ferrite billet can be used to promote magnons at high energy density. In some embodiments, many magnetic materials may possess magnon signatures for energy harvesting. In these embodiments, the power output may be a strong function of the battery voltage and the pumping frequency. In one embodiment, the magnon density is an emerging feature of the pumping of the ferromagnetic ferrite billet. The resonant coupling has antenna action for the neutrino flux capturing. Similarly, SLW's may be the primary entity for energy conversion.

A magnon Bose-Einstein Condensate (mBEC) has recently been found to achieve a new form of magnetism inside ferrite compounds such as Yttrium Iron Garnet (YIG). A strontium ferrite magnetic billet employed herein, in some embodiments, has properties that result with conditions below the phase change boundary. This BEC condition is not always fully achievable, yet interesting new properties may still exist. The BEC involves a phase change into a coherent, collective motion. Prior to this phase change the magnetic properties may have promising aspects that is termed a Sub-Threshold magnon Bose-Einstein Condensate or an STmBEC, for short.

A STmBEC formation requires resonantly enhanced electric and magnetic fields inside the billet approaching a mBEC. This new form of STmBEC magnetism has a unique property that is of unknown conditions. It interacts with the neutrino flux and provides a source of useful electric power while at the same time cooling the billet. Neutrinos waves are energetic and are produced in copious quantities by every star. As such, they represent a superior solar energy source that can be accessed with three-axes conditions with magnetic ferrite cores. These are quantum mechanical wave interactions between neutrinos and the STmBEC materials. This phenomenon acts very differently from customary transverse EM waves (photons).

The magnetic and electric fields surrounding the three-axes coils or wires are generally transverse to the wire axis. The waves following the wires interact with environment to create a longitudinal spin wave with yet to be determined properties. In one embodiment, the three-axes wiring forms a novel transformer circuit when resonantly coupled to a magnetostrictive ferrite core.

Magnetostrictive materials expand and contract longitudinally with the application of magnetic fields. In this invention the three-axes windings around the ferrite core couple resonantly to bistable properties and establish the conditions to amplify and convert the flux of neutrinos. Applying these longitudinal waves couple resonantly to the neutrinos in the STmBEC condition constitutes an antenna for harvesting neutrino energy. The action of the neutrinos with the STmBEC material results in a magnetic pulse sent into the three-axes coils. This in turn, induces current pulses which are sent into the battery. This is how the battery charges. This is the mechanism for producing clean electrical power back into the battery.

Disclosed in an embodiment is a system configured to harvest energy from astronomical conditions. In some embodiments, the device produced a power of 60 watts in sustaining the voltage of a lithium-ion battery pack at about 300 pounds and at about 175 volts for a period of at least two months, or at least four months, or at least six months without significant degradation. There are no restrictions imposed by the Laws of Thermodynamics regarding the new energy conversion process. Harvesting this abundant supply of energy from the neutrinos permeating space confirms the presence of this newly accessible energy reservoir.

### Axions

Axions are another well-motivated dark matter candidate. However, they resist identification as much as neutrinos do. Experts do not agree on the properties such as mass or lifetime. While axions are much lighter than the supersymmetry (SUSY) relics and are produced by a very different mechanism, they are indistinguishable to theoretical cosmologists studying galaxy formation and the origin of large-scale structure. Both axions and SUSY relics behave as cold dark matter and cluster effectively to form galaxies and large-scale structure.

Axions were originally proposed to explain the lack of CP violation (violation of CP-symmetry or charge conjugation parity symmetry) from strong interactions. They are associated with a new U(1) symmetry: the Peccei-Quinn (P-Q) symmetry. As originally proposed, axions interacted strongly with matter. When experimental searches failed to detect axions, new models were proposed that evaded experimental limits and had the interesting consequence of predicting a potential dark matter candidate.

In the early universe, axions can be produced through two very distinct mechanisms. At the quantum chromodynamic phase transition, the transition at which free quarks were bound into hadrons, a BEC of axions form and these very cold particles would naturally behave as cold dark matter. Axions can also be produced through the decay of strings formed at the P-Q phase transition. Unless inflation occurs after the P-Q phase transition, string emission is thought to be the dominant mechanism for axion production. Axionic strings will not produce an interesting level of density fluctuations as their predicted mass per unit length is far too small to be cosmologically interesting.

### Theoretical Explanation of the Physics

In 1931, P.A.M. Dirac combined equations of relativity and quantum mechanics. His effort predicted the existence of the positron and suggested the existence of magnetic monopoles. In 2012, George Lochak, former president of the Institut de Louis DeBroglie, completed Dirac's work on how a short-lived monopole could account for the interactions between the magnon BEC and the neutrino flux the monopoles enable these interactions.

Magnetic monopoles are just as elusive as neutrinos and axions, but they are a possible short-lived catalyst for cojoining neutrinos with axions. The catalysis is made possible by the magnons interior to the billet under condensate conditions. The strong magnetic flux input due to the rise of the AC current is the source over the crystal lattice of a BEC comprised of a quantum of magnetic charges.

This BEC is short-lived while the current AC surges. This dense field of magnetic flux quanta interacts with neutrinos. The magnon density inside the billet is related to the power input profile. The discovery of the neutrino flux — STmBEC interaction opens the door for understanding intrinsic properties of both entities.

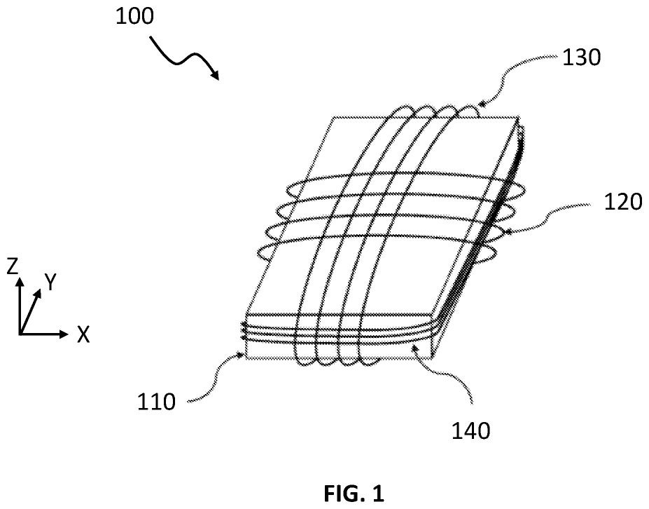

FIG. 1 is a device 100 configured to harvest energy from the environment according to an embodiment. In this embodiment, the device 100 includes a billet core 110. In some embodiments, the billet core 110 may be formed of a ferrite solid material, a ferroelectric solid material, or a ferrostrictive solid material, among other suitable materials. In one embodiment, the billet core 110 is a ferrite billet with a plurality of coils 120, 130, 140 adjacent at least a portion of the billet core 110. For example, the billet core 110 may include a plurality of windings or coils wrapped about an x-axis 120 of the billet core 110, a plurality of windings or coils wrapped about a y-axis 130 of the billet core 110, and a plurality of windings or coils wrapped about a z-axis 140 of the billet core 110. The windings or coils 120, 130, 140 may be copper wires (e.g., 20-gauge) or other suitable metal wires or coils. In some embodiments, the windings or coils 120, 130, 140 may be bifilar wires circumferentially wrapped around the billet core 110 about the respective axes as discussed above. The bifilar wires will be described in more detail below.

In operation, resonant coupling between the billet core 110 (e.g., ferrite billet) and the windings or coils 120, 130, 140 (e.g., bifilar windings) about the three axes (e.g., x-axis, y-axis and z-axis) can result in an antenna absorbing the energy of the neutrinos emanating from the sun. In one embodiment, the billet core 110 may be formed of strontium ferrite (SrFeOx) material. Strontium ferrite (SrFeOx) is a billet material with a demonstrated ability to produce power. It can be strongly magnetic, electrically resistive and magnetorestrictive. The alternating current (AC) input around the billet core 110 can be combined into a single resonant frequency that forms the STmBEC and increases the antenna's frequency for absorbing energy from the flux of neutrinos.

In another embodiment, the billet core 110 may be blended with a metallic element. In some embodiments, the metallic element can be strontium, barium, manganese, nickel or zinc, among other suitable metals, compounds or chemical compositions. In an embodiment, the billet core 110 can be processed with a grain dimension of less than about 100 nanometers. In another embodiment, the grain dimension may be less than about 50 nanometers, among other suitable grain sizes or dimensions. In one embodiment, the billet core 110 may be magnetically conditioned to produce field gradients to maximize the energy from the environment for charging the battery 210. This will be discussed in more detail below.

In one embodiment, the device 100 can act as a transmitter and receiver of neutrino waves. As discussed above, the properties of these waves are still controversial, but they are produced in every star and can pass through matter without any interaction. Consequently, the Earth is awash with high energy densities of these energetic waves that can be harvested for its clean electrical power and energy. In some embodiments, the device 100 can produce power of at least about 10 watts, or at least about 20 watts, or at least about 30 watts, or at least about 40 watts, or at least about 50 watts, or at least about 60 watts continuously for over at least about two months, or at least about four months, or at least about six months with no signs of degradation.

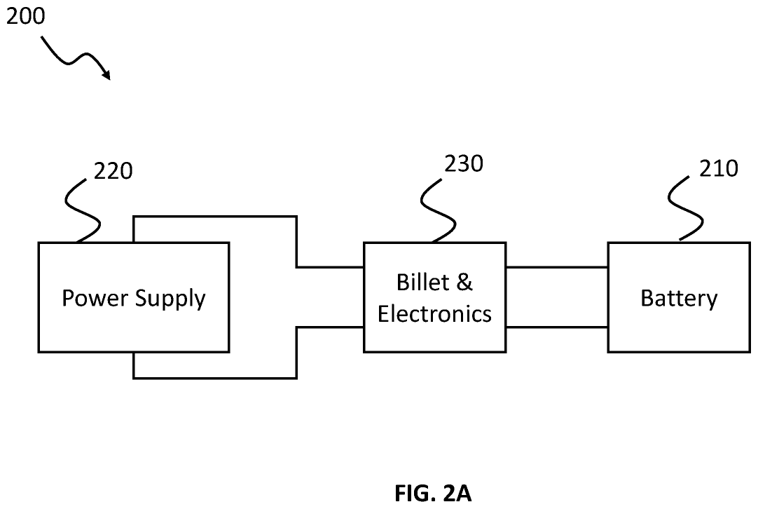

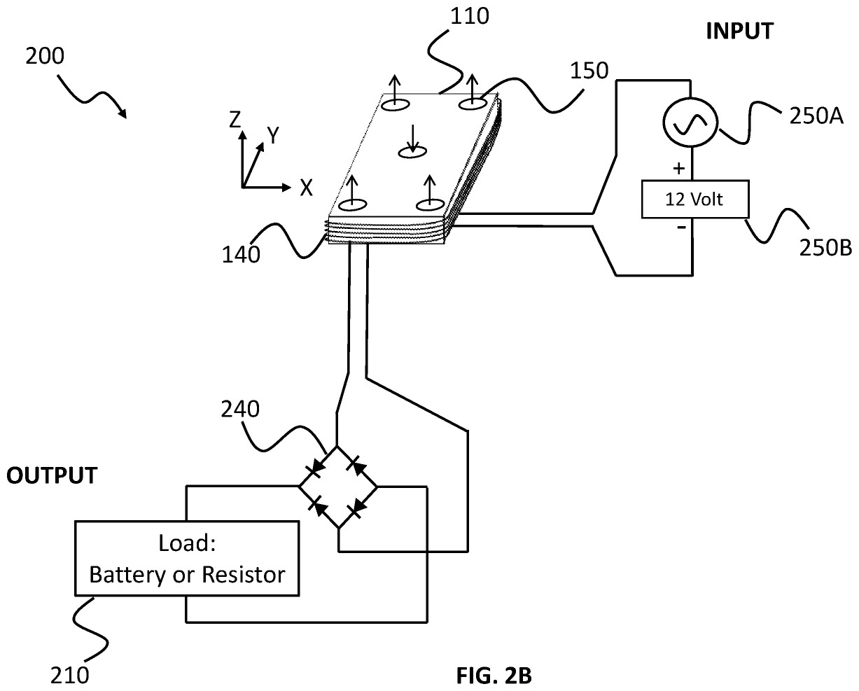

FIG. 2A is an apparatus 200 configured to harvest energy from the environment according to an embodiment. In this embodiment, the apparatus 200 includes a battery 210, a power supply 220, and a billet core 110 similar to that described above together with pulsed electronics 230. In one embodiment, the battery 210 is a load battery, the power supply 220 is a direct current (DC) power supply and includes a battery transformer and DC to AC converter, and the billet core 110 and pulsed electronics 230 includes an electromagnetic zone having the coiled ferrite billet as the billet core 110.

In one embodiment, the battery 210 may be a lithium-ion battery pack. In operation, the battery 210 powers the power supply 220, and in turn, the power supply 220 may be configured to resonantly charge the battery 210. In another embodiment, the billet core 110 may be resonantly coupled to the battery 210 for charging the battery 210 with the energy from the environment. In other words, energy from the environment may be directed to charge the battery 210.

In an embodiment, the energy directed to charge the battery 210, from the environment, can be accomplished without current flowing through the plurality of coils 120, 130, 140 wrapped about the billet core 110. This can be accomplished due to the resonant coupling or charging effect. The energy from the environment can include neutrino waves emitted by a star or energy from magnetic monopoles. In other embodiments, the energy directed to charge the battery 210 can be accomplished through the plurality of coils 120, 130, 140 wrapped about the billet core 110.

FIG. 2B is an apparatus 200 configured to harvest energy from the environment according to another embodiment. In this embodiment, the apparatus 200 includes electronics and the ferrite billet 110 similar to that described above. For example, the ferrite billet 110 includes a plurality of z-axis windings 140. In this instance, there may be two sets of coils wrapped around the z-axis 140, one set of coils directed to input and the other set of coils directed to output. In this embodiment, the ferrite billet 110 may further include conditioned cylinders 150, which will be discussed in more detail below.

In one embodiment, the apparatus 200 includes a pulse rectifier 240 (e.g., full rectifier) connecting to, on the output side, return lines of a load 210, which can include a battery or a resistor. On the input side (e.g., to the z-axis windings 140), unipolar and bipolar pulses can be applied to the wrapped billet 110, in conjunction with positive terminal 250A and negative terminal 250B on the battery. In other words, electrical inputs such as unipolar pulses or bipolar pulses can be applied to the billet core 110. In another embodiment, the z-axis windings 140 can receive rapid risetime, unipolar pulses from the power supply. In this instance, power and frequency of the resonant supply are critical. At resonance, the billet core 110 can change phase and form a STmBEC thereby becoming an antenna for receiving neutrinos coming from the sun.

In one embodiment, the apparatus 200 results in the formation of a STmBEC causing voltage amplification in each pulse. The apparatus 200 can serve several functions. It is both a receiver and emitter of waves. In addition, the apparatus 200 can be an amplifier of neutrino energy. The resonant pulsing electronics can tune the receiver for maximum amplification. A high Q circuit maximizes the energy conversion by the STmBEC environment.

In one embodiment, an embodiment according to the apparatus 200 continuously charged a 300 pounds lithium-ion battery pack. This charging process continued for months (e.g., at least six months) at an output of at least about 30 watts. After this first period of time, in another embodiment, the number of batteries in the pack was increased to a series voltage level of about 185 volts and the power output increased to about 60 watts. In operation, a modest increase in battery voltage had a big effect on the power output. The apparatus 200 ran for at least an additional six months at this higher power output.

In short, neutrino energy can be converted with an arrangement of wires surrounding the three-axes strontium ferrite billet, and unipolar and bipolar pulses can be applied to the wrapped ferrite billet. The wires surrounding the billet block cause dilation of the ferrite core in each direction of the three axes. Winding bifilar wires around each of the three axes allow for resonance that renders the apparatus as both a source and an absorber of neutrino energy. In one embodiment, the apparatus is also able to act as both transmitter and receiver of these waves. Additionally, the apparatus is able to serve as an amplifier of neutrino energy. In another embodiment, the resonant pulsing electronics can tune the receiver for maximum amplification.

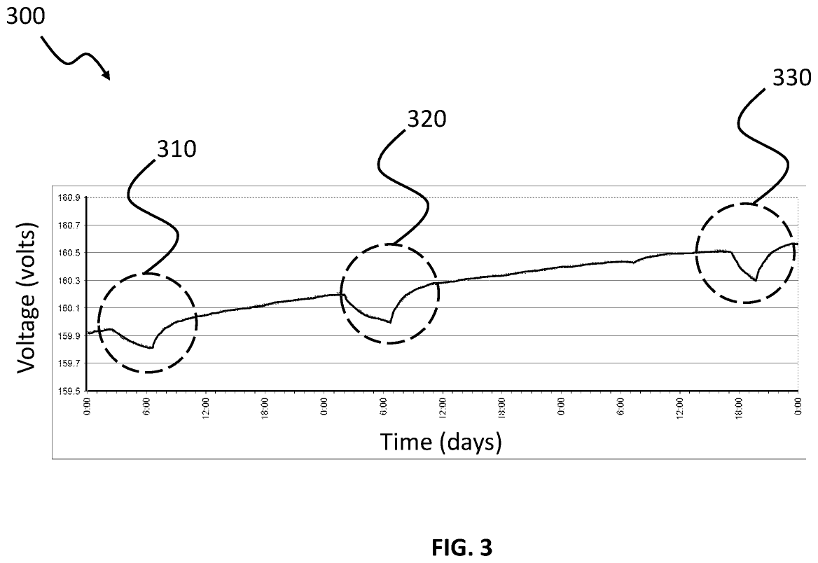

FIG. 3 is a battery charging profile 300 of an apparatus 200 according to one embodiment. The voltage may be monitored with data-logging Fluke multimeters periodically recording the voltage at certain time intervals. In this embodiment, the battery pack is at from about 165 volts to about 167 volts, with about 30 watts of power charging the battery for about 7 days. In general, the voltage versus time signal of the charging profile 300 demonstrated monotonically rising voltage with time over a period of at least a week with the exception of three events 310, 320, 330. Each of the events 310, 320, 330 can be associated with “dips” in voltage measurements which has been observed to coincide with three different instances of coronal mass ejections. Coronal mass ejections from the sun can produce an increase in neutrinos impacting the earth's magnetosphere. In some instances, over-charging events, e.g., nova explosions, may cause components within an apparatus 200 to burn out thereby leading to catastrophic failures.

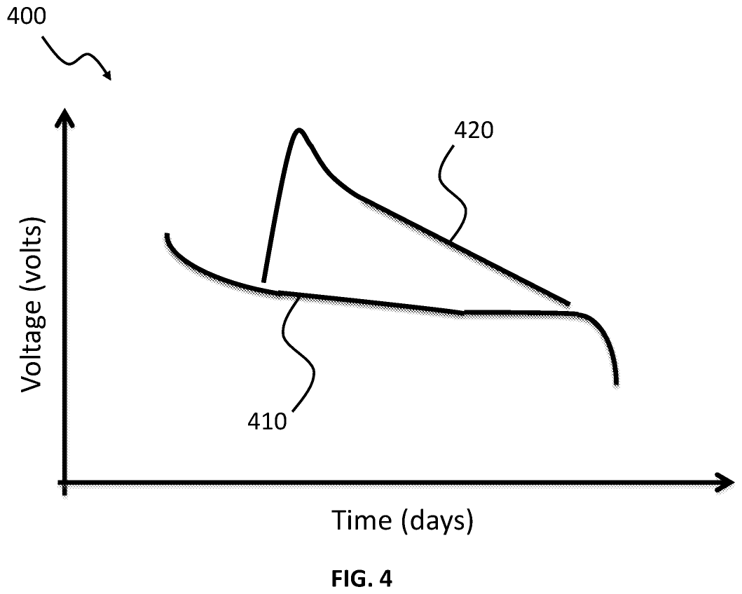

FIG. 4 is a battery charging profile 400 of an apparatus 200 according to another embodiment. In this embodiment, an about 69 volts battery is drawn down with power at about 10 watts. In charging profile 410, the battery demonstrated steady discharge until depletion after about 16 days. In some ways the battery behaved similar to that of a normal S-curve for battery operation. In charging profile 420, a rapid over-charging anomaly can be observed which may be related to a nova explosion. In that instance, photons and neutrinos may arrive at Earth simultaneously and cause the battery pack to overcharge itself (e.g., spontaneously self-charge) to exceedingly high voltage levels. As shown, the over-charging anomaly of the charging profile 420 may be coincident with the arrival of a nova emission (e.g., anomalous voltage recordings within three-hour window of a nova event). It will be worthy to note that nova events may occur thousands of years ago and the first photos from that event (or any other earlier events from tens or hundreds of years) may not arrive at Earth until recent years. It will also be appreciated that nova events in our galaxy may be the cause of the over-charging anomalies as exhibited and correlated by the charging profiles of the batteries according to presently disclosed apparatus embodiments.

In some embodiments, the charging profiles 300, 400 in FIGS. 3 and 4 serve to identify the efficacy of a tuned STmBEC antenna/receiver system. In other words, a STmBEC apparatus or system according to the present disclosure needs to be properly tuned to minimize or mitigate any over-charging events.

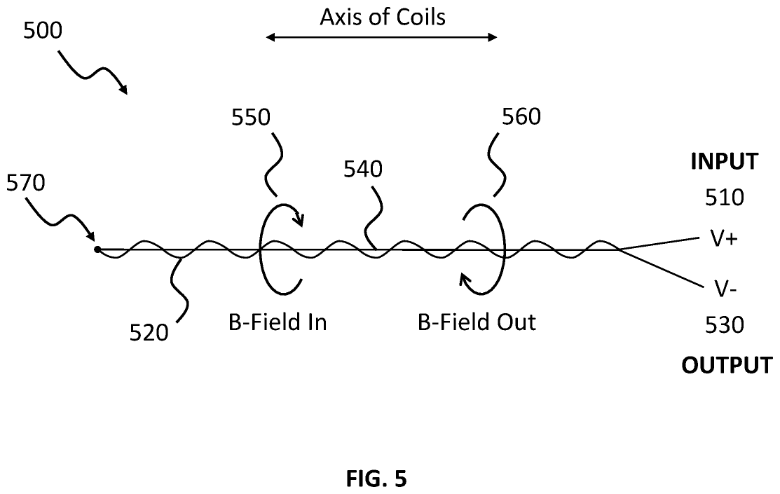

FIG. 5 is a bifilar wire or coil winding 500 according to an embodiment. The wire or coil winding 500 are similar to the plurality of windings or coils 120, 130, 140 as discussed above. As shown, the coil winding 500 can include a first wire 520 twirling around a second wire 540. The first wire 520 may be a twirling wire and the second wire 540 may be a central wire. In some instances, the pair of wires 520, 540 may spiral in a polar fashion. In one embodiment, the two wires 520, 540 may be joined at about a soldered end 570 whereby the coil winding 500 becomes a single wire with two ends, an input voltage end 510 and an output voltage end 530.

Magnetic and electric fields surrounding the wires 520, 540 are generally transverse to the wire axis. A current applied to the two wires 520, 540 will move along in countervailing paths that cancel the magnetic fields (B-Fields) leaving a purely electric wave moving down the axis of the wire. In other words, current applied to the first wire 520 may generate an inward magnetic field 550 while current applied to the second wire 540 may generate an outward magnetic field 560, whereby the magnetic fields 550, 560 cancel each other resulting in a purely electric wave traveling along the axis of the coils as shown by the double arrows.

The twirled wire with canceled magnetic fields (B-fields) can result in interesting magnetic responses. In one embodiment, the bifilar wiring forms a novel transformer circuit when resonantly coupled to a magnetostrictive ferrite core. Magnetostrictive materials expand and contract longitudinally with the application of magnetic fields. The bifilar windings around the ferrite core couple resonantly to bistable properties and establish the conditions to receive and amplify atmospheric neutrinos. Applying this pure electric and scalar longitudinal wave to a magnetostrictive ferrite core establishes a “second wave” which can be a longitudinal magnetic wave. Coupling the neutrinos resonantly to the BEC constitutes an antenna for harvesting energy. The BEC can be formed with the aid of a pure electric wave that responds differently to magnetic materials such as ferrite transformer cores. The scalar waves amplify the electric fields in a transformer resonant circuit and energy conversions can be achieved as BEC formation requires resonantly enhanced electric fields inside the billet.

In one embodiment, a strontium ferrite (SrFeOx) billet core 110 can have the following dimensions: about 15 cm (length) by about 10 cm (width) by about 2.5 cm (thickness) with a weight of about 1 kilogram. In some embodiments, the billet core 110 can be formed with other sizes and dimensions. The z-axis 140 of the billet core 110 can be wrapped with bifilar coiling wires 500 that are about 30 meters in length. One of the 30-meter length wires may act as the resonant input. A second wire may be co-axially wrapped around the first wire to convey the increased energy back to the battery 210. In some embodiments, all three perpendicular axes (e.g., x-axis, y-axis and z-axis) of the billet core 110 can be wrapped with bifilar coiling wires that are about 60 meters in length, among other suitable lengths. The thickness of the wires may be at about 20 gauge, or other suitable thicknesses. The inductance and the capacitance may be low due to bifilar induced cancelations. The bifilar windings can send current in the forward and reverse directions causing cancelation of the magnetic field circulating around the paired wires. As a result, the electric field which is normally perpendicular to the wire axis becomes a longitudinal electric wave circulating around the billet core 110. Consequently, that action together with the BEC environment can capture neutrinos from local space.

The appearance of a First Law violation can be accounted for by the heretofore unnoticed input from the STmBEC interaction with the wire-wounded billet core 110. The thickness of the above wires 500 may be at about 20 gauge. The inductance and the capacitance of the above apparatus can be lowered due to the bifilar induced limitations. Consequently, the resonant frequency allows the STmBEC environment to capture neutrinos from local space. The rate of power conversion is expected to increase as the size of the billet/antenna increases. In this embodiment, the energy conversion of the tested billet core 110 produced a continuous 60 watts of battery charging power. This represents over 100 times (or at least greater than 50 times) the energy density of a solar cell of the same dimension.

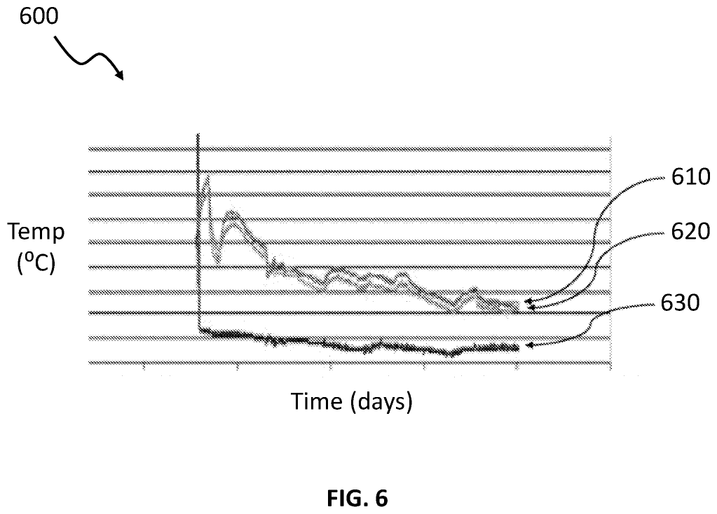

FIG. 6 are temperature profiles 600 of an apparatus 200 according to an embodiment. In this instance, the light bulb operated at about 60 watts over a six-day period running under the hood of a car, where the car was allowed to operate during the first two days. As measured, the temperature profile 600 demonstrate the ability of the apparatus 200 and the ferrite billet core 110 to carry out sub-ambient operations. Profiles 610 and 620 are two thermistors mounted in the trunk of a car while profile 630 is that of a thermistor mounted on top of a ferrite billet core 110 embodiment showing considerable cooling being observed. When the ferrite billet core 110 is producing about 60 watts, cooling of the ferrite billet core 110 below ambient conditions confirms that a new physical phenomenon is in operation, because the Laws of Thermodynamics prohibits an isolated cold object. The cooling effect was unanticipated until the mBEC development matured.

The electronic circuits for achieving an RLC (resistor, inductor, capacitor) resonance with the wrapped billet core 110 is straight forward: batteries with low impedance will produce high efficiency. In one embodiment, the antenna system similar to those described in FIGS. 2A-2B can resonate at about 137 kilohertz (KHz) and the resonant tuning can be constant for an extended period of time (e.g., over six months). The calculated resonance for the wrapped billet core 110 turned out to be at about 146 KHz further affirming confidence of the resonant effects on the STmBEC. It will be understood and appreciated that the disclosed embodiments herein can be tuned to resonate at other suitable frequencies.

In one embodiment, efficient conversion of ambient neutrino wave energy can be a function of impedance matching of the triple resonance of the three wrapped bifilar wires 120, 130, 140. In another embodiment, efficient conversion can be a function of impedance matching of the z-axis resonance of the wrapped wires 140. In one embodiment, the billet/wire apparatus 200 can be subject to AC input on the electrical energy supplied from a battery 210. The power output is a strong function of the battery voltage. For example, the power output can be at about 28 watts when the battery voltage is at about 165 volts. And it can be at about 60 watts when the battery input voltage is raised to about 185 volts with no other changes to the system 200. The interaction of the three-axes windings 120, 130, 140 with the unique magnetic field inside the STmBEC is allowed in the ferrite billet material system 200.

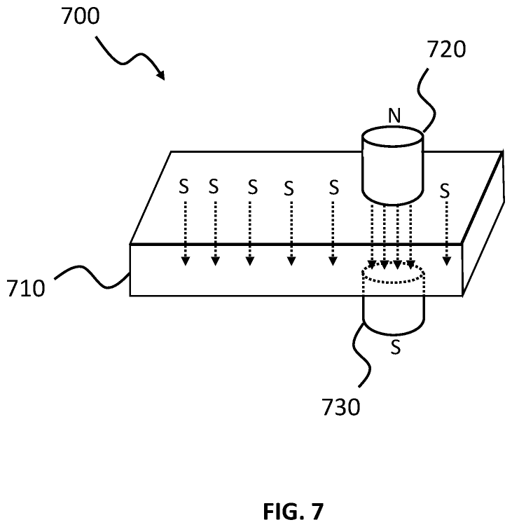

FIG. 7 is an illustration of magnetic conditioning 700 of a billet core 710 according to an embodiment. A BEC is intolerant of magnetic inhomogeneities and may benefit by intentionally forming variations. For example, magnetic conditioning is a modification of the magnetic field distribution. In one embodiment, the ferrite billet 710 has a dimension of about 6 inches (length) by about 4 inches (width) by about 1 inch (thickness) with a top face being south pole and a bottom face being north pole. A first cylindrical permanent magnet 720 made of neodymium (NdFeB) with a surface field strength of about 0.15 Tesla can be placed on one side of the ferrite billet 710, while a second similar magnet 730 can be placed on the opposite side. In this embodiment, conditioning can be achieved by positioning two neodymium (NdFeB) magnets 720, 730 on opposite sides of the one-inch-thick ferrite billet 710 to “coerce the magnetic field” in creating a cylindrical magnet inversion region. In other embodiments, the ferrite billet 710 can take on other dimensions and sizes.

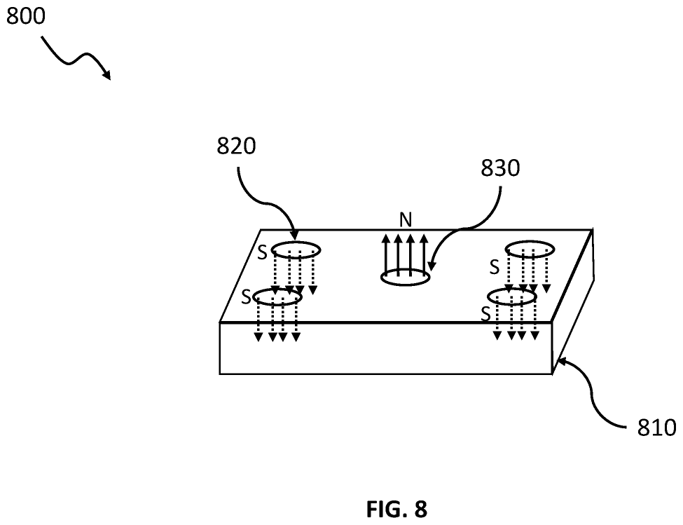

FIG. 8 is an illustration of conditioning 800 with complex field arrangement according to another embodiment. In this embodiment, the ferrite billet 810 initially has top face north pole with cylindrical magnetic diversion (e.g., cylindrical NdFeB conditioning magnets an inch in diameter by an inch tall) on four corners 820 of the billet 810 leaving a north facing field about the center 830 of the billet 810. Collectively, the permanent magnets about the corners 820 may have a field strength of over about 1 Tesla thereby coercing the magnetic field to line up between opposing magnets. Visualization can be observed using a mylar film impregnated with iron filings.

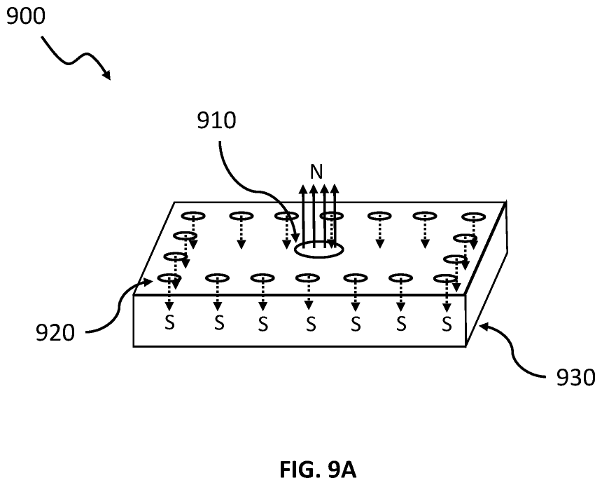

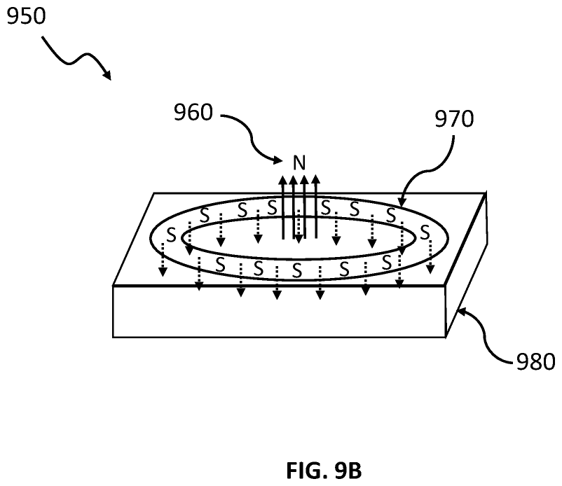

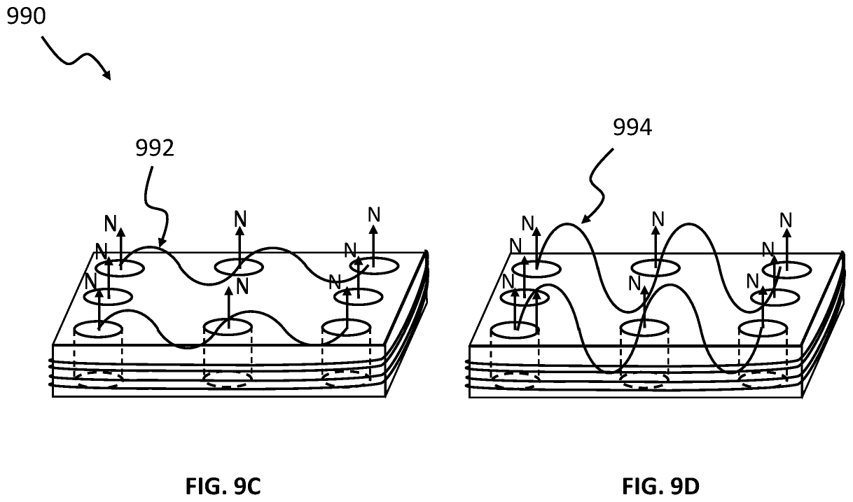

FIGS. 9A-9B illustrate two different conditioned billets 900, 950 in accordance with the present disclosure. In these embodiments, polarity of the newly stratified magnetic regions can be determined by polarity of the coercive magnets. FIG. 9A shows a ferro-magnetic billet 900 having a central north facing pole 910 with a plurality of coerced cylindrical regions 920 distributed about the peripherals of the ferro-magnetic billet 900. In operation, the coerced cylindrical regions 920 have south-facing fields 930. Similarly, FIG. 9B shows a ferro-magnetic billet 950 also having a north facing pole about a center region 960. In this example, a plurality of NdFeB magnets form a circular loop 970 around the center region 960, the plurality of NdFeB magnets having south-facing fields 980.

FIGS. 9C-9D illustrate the flexibility that can be achieved with high strength ferrite billets 990 where various shapes and field strengths of ferrite billets 990 can be achieved by directing cylindrical magnets in different patterns. FIG. 9C shows the ferrite billet 990 with low voltage field where the E-field is at sub-threshold intensity 992. The field strength can be increased, by the disclosed magnetic conditioning techniques, among other methods, to exceed a threshold value for condensate retention 994.

While the ferrite billets 700, 800, 900, 950, 990 as shown in FIGS. 7-9 are generally rectangular in shape, it will be appreciated by one skilled in the art that the ferrite billets 700, 800, 900, 950, 990 can take on other geometric shapes (e.g., circular, square), sizes and compositions.

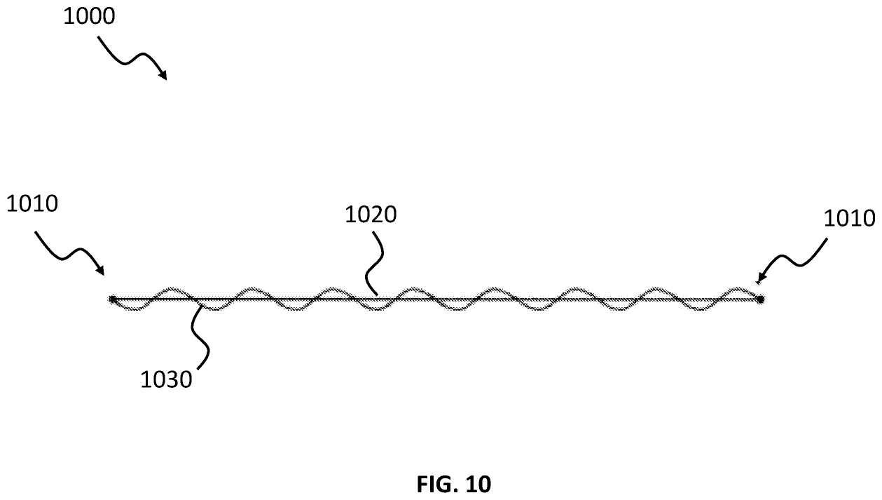

FIG. 10 is a bifilar wire or coil winding 1000 according to another embodiment. The wire or coil winding 1000 is substantially similar to the wire or coil winding 500 as discussed above in FIG. 5 and may be used as the plurality of windings or coils 120, 130, 140 for the billet core 110. As shown, the coil winding 1000 includes a first wire 1030 twirling or winding around a second wire 1020. In this embodiment, both ends of the coil winding 1000 may be soldered 1010. Consequently, the magnetic fields (B-fields) of the coil winding 1000 are not canceled because the bifilar windings are soldered at both ends 1010. In operation, when the bifilar wires have both ends soldered 1010, the bifilar wires may act like a normal wire with twice the conductivity. In other words, the conductivity of the coil winding 1000 can be improved by nearly 50% in comparison with the conductivity of the coil winding 500 which only has one soldered end 570.

In one embodiment, the bifilar wire is soldered at one end and the B-field is not canceled. In another embodiment, the bifilar wire is soldered at one end and the B-field is canceled. In one embodiment, the bifilar wire is soldered at both ends and the B-field is not canceled. In another embodiment, the bifilar wire is soldered at both ends and the B-field is canceled.

In one embodiment, the billet is wrapped with bifilar wires that are soldered at one end to create pure electric wave in all three directions (e.g., x-axis, y-axis and z-axis). In another embodiment, the billet is wrapped with bifilar wires that are soldered at both ends to create pure electric wave in all three billet directions.

In one embodiment, the z-axis 140 of the billet core 110 (e.g., inside coil) can be wrapped with two bifilar coiling wires 1000 as input connecting to the pulse forming network 230. In this embodiment, the billet core 110 can be wrapped with an additional 10 meters of the 20-gauge bifilar 1000 connecting the billet core 110 back to the battery 210.

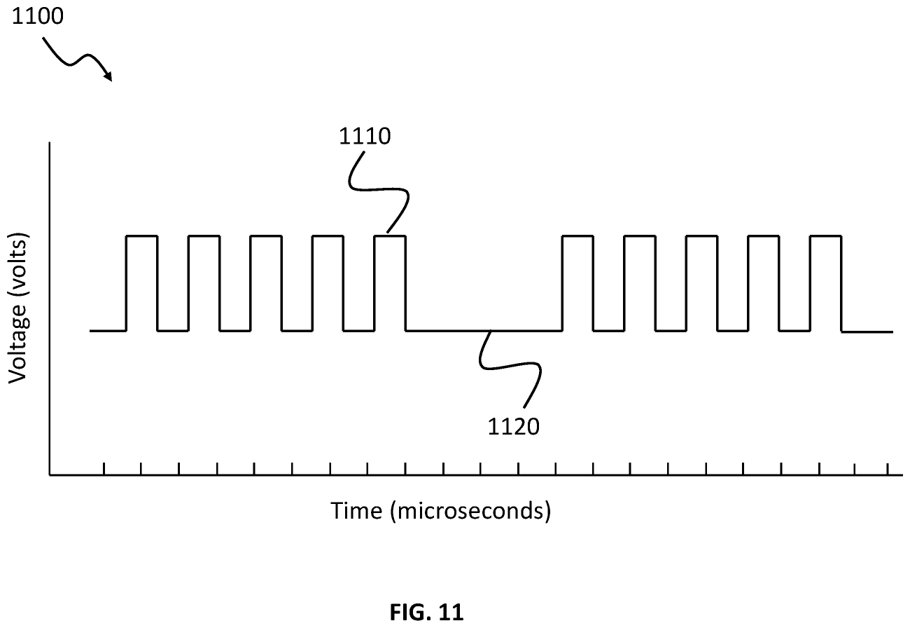

FIG. 11 is an exemplary square wave 1100 input that may be used in conjunction with the present disclosure. In one embodiment, the square wave 1100 may have a peak voltage 1110 at variable frequencies in order to search for E-field resonances, with duty cycle 1120 having variable on/off sequences.

Having described above several aspects of at least one example, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents

While example embodiments have been particularly shown and described, it will be understood by those skilled in the art that various changes in form and details may be made therein without departing from the scope of the embodiments encompassed by the appended claims. For example, other useful implementations could be achieved if steps of the disclosed techniques were performed in a different order and/or if components in the disclosed systems were combined in a different manner and/or replaced or supplemented by other components. Accordingly, other implementations are within the scope of the disclosure.

What is claimed is:

1. An apparatus comprising:
a battery;
a power supply;
a billet core; and
a plurality of coils adjacent at least a portion of the billet core, the billet core configured to harvest energy from an environment.

2. The apparatus of claim 1, wherein the battery is a lithium-ion battery pack.

3. The apparatus of claim 1, wherein the battery powers the power supply.

4. The apparatus of claim 3, wherein the power supply is configured to resonantly charge the battery.

5. The apparatus of claim 1, wherein the billet core is formed of a ferrite solid material.

6. The apparatus of claim 1, wherein the billet core is formed of a ferroelectric solid material.

7. The apparatus of claim 1, wherein the billet core is formed of a ferrostrictive solid material.

8. The apparatus of claim 1, wherein the billet core is processed with a grain dimension of less than about 100 nanometers.

9. The apparatus of claim 1, wherein the billet core is magnetically conditioned to produce field gradients to maximize the energy from the environment for charging the battery.

10. The apparatus of claim 1, wherein the billet core is resonantly coupled to the battery for charging the battery with the energy from the environment.

11. The apparatus of claim 1, further comprising a metallic element blended with the billet core, the metallic element selected from the group consisting of strontium, barium, manganese, nickel and zinc.

12. The apparatus of claim 1, wherein the plurality of coils adjacent at least a portion of the billet core includes a plurality of bifilar wires circumferentially wrapped around the billet core.

13. The apparatus of claim 12, wherein the plurality of bifilar wires includes copper coils.

14. The apparatus of claim 1, wherein the energy from the environment is directed to charging the battery.

15. The apparatus of claim 14, wherein the energy directed to charging the battery can be accomplished without current flowing through the plurality of coils.

16. The apparatus of claim 1, wherein the energy from the environment includes neutrino waves emitted by a star.

17. The apparatus of claim 1, wherein the energy from the environment includes energy from magnetic monopoles.

18. The apparatus of claim 1, further comprising electrical input to the billet core including unipolar pulses.
